(19) United States
(12) Patent Application Publication
(10) Pub. No.: US 2025/0075307 A1
(43) Pub. Date: Mar. 6, 2025

(54) MASK ASSEMBLY AND METHOD OF MANUFACTURING THE SAME

(71) Applicant: Samsung Display Co., LTD., Yongin-si (KR)

(72) Inventors: Seung Jin LEE, Yongin-si (KR); Yeon Ju KANG, Yongin-si (KR); Sang Hoon KIM, Yongin-si (KR); Sang Shin LEE, Yongin-si (KR); Min Ji JANG, Yongin-si (KR)

(73) Assignee: Samsung Display Co., LTD., Yongin-si (KR)

(21) Appl. No.: 18/774,208

(22) Filed: Jul. 16, 2024

(30) Foreign Application Priority Data
Aug. 29, 2023 (KR) 10-2023-0113973

(51) Int. Cl. C23C 14/04

(52) U.S. Cl. CPC C23C 14/042

(57) ABSTRACT

The disclosure relates to a mask assembly and a method of manufacturing the mask assembly. A mask assembly includes a frame including a frame opening, and an open mask including cell openings overlapping the frame opening. The open mask further includes support portions overlapping remaining cell openings except a first cell opening among the cell openings.

### CROSS-REFERENCE TO RELATED APPLICATION(S)

This application claims priority to and benefits of Korean Patent Application No. 10-2023-0113973 under 35 U.S.C. § 119, filed on Aug. 29, 2023, in the Korean Intellectual Property Office, the entire contents of which are incorporated herein by reference.

### BACKGROUND

### 1. Technical Field

Embodiments relate to a mask assembly and a method of manufacturing the mask assembly.

### 2. Description of the Related Art

As information technology has developed, importance of a display device, which is a connection medium between a user and information, has been highlighted. Accordingly, the use of display devices such as a liquid crystal display device, an organic light emitting display device, and the like has been increasing.

A display device may include a plurality of pixels. Each of the plurality of pixels may include a light emitting layer disposed between opposing electrodes. The light emitting layer may be formed through various methods, one of which may be a deposition method using a mask assembly.

The mask assembly may be manufactured by attaching a plurality of masks to a frame. In the process of attaching the plurality of masks, the shape of the mask is deformed, which deteriorates deposition accuracy and reliability of the light emitting layer.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments have been made in an effort to provide a mask assembly with improved deposition accuracy and reliability and a method of manufacturing the mask assembly.

According to an embodiment, a mask assembly may include a frame including a frame opening; and an open mask including a plurality of cell openings overlapping the frame opening, wherein the open mask may further include a plurality of support portions overlapping remaining cell openings except a first cell opening among the plurality of cell openings.

Each of the plurality of cell openings may have a substantially rectangular shape.

A diagonal length of each of the plurality of cell openings may be about 11 inches or more.

The mask assembly may further include a first deposition mask including a first deposition area overlapping the first cell opening.

Each of the plurality of support portions may extend in a first direction and may be disposed in a second direction substantially perpendicular to the first direction.

The plurality of support portions may include a plurality of first sub-support portions each extending in a first direction and disposed in a second direction substantially perpendicular to the first direction, and a plurality of second sub-support portions each extending in the second direction and disposed in the first direction.

According to an embodiment, a method of manufacturing a mask assembly may include manufacturing an open mask including n cell openings, where n is a natural number of 3 or more, and a plurality of support portions overlapping remaining cell openings except a first cell opening among the n cell openings; attaching the open mask to a frame including a frame opening so that the plurality of cell openings overlap the frame opening; and attaching a first deposition mask including a first deposition area to the open mask so that the first deposition area overlaps the first cell opening.

The method of the mask assembly may further include removing support part portions that overlap a k-th cell opening following a (k-l)-th cell opening among the plurality of support portions, and attaching a k-th deposition mask in which a k-th deposition area is defined to the open mask so that the k-th deposition area overlaps the k-th cell opening, where k is a natural number of 2 or more and n or less.

The removing of the support part portions and the attaching of the k-th deposition mask may be repeated until the value of k becomes n.

The attaching may include applying a tensile force to the first deposition mask, welding the stretched first deposition mask to the open mask, and releasing the tensile force.

The attaching may include applying a tensile force to the k-th deposition mask, welding the stretched k-th deposition mask to the open mask, and releasing the tensile force.

Each of the n cell openings may have a substantially rectangular shape.

A diagonal length of each of the n cell openings may be about 11 inches or more.

Each of the plurality of support portions may extend in a first direction and may be disposed in a second direction substantially perpendicular to the first direction.

The plurality of support portions may include a plurality of first sub-support portions each extending in a first direction and disposed in a second direction substantially perpendicular to the first direction, and a plurality of second sub-support portions each extending in the second direction and disposed in the first direction.

According to an embodiment, a method of manufacturing a mask assembly may include attaching a mask to a frame including a frame opening; forming a k-th cell opening in the mask; and attaching a k-th deposition mask including a k-th deposition area to the mask so that the k-th deposition area overlaps the k-th cell opening, where k is a natural number greater than or equal to 1 and less than or equal to n, and n is a natural number greater than or equal to 3.

The forming of the k-th cell opening and the attaching of the k-th deposition mask may be repeated until the value of k becomes n.

The k-th cell opening may be formed by irradiating the mask with a laser beam.

The k-th cell opening may have a substantially rectangular shape.

A diagonal length of the k-th cell opening may be about 11 inches or more.

According to embodiments, it is possible to improve deposition accuracy by forming a plurality of support portions overlapping a plurality of openings in an open mask to prevent deformation of the open mask. It is possible to improve deposition reliability by sequentially removing a plurality of support portions to secure a space in an opening.

However, the effects of the disclosure are not limited to the above-described effects, and may be variously extended without departing from the spirit and scope of the disclosure.

### BRIEF DESCRIPTION OF THE DRAWINGS

The above and other features of the disclosure will become more apparent by describing in further detail embodiments thereof with reference to the accompanying drawings, in which:

FIG. 1 illustrates a schematic perspective view of a mask assembly according to an embodiment.

FIG. 2 and FIG. 3 illustrate a manufacturing process of a mask assembly.

FIG. 4 illustrates a mask assembly according to an embodiment.

FIG. 5 to FIG. 12 schematically illustrate a manufacturing process of a mask assembly according to an embodiment.

FIG. 13 illustrates a mask assembly according to an embodiment.

FIG. 14 to FIG. 24 schematically illustrate a manufacturing process of a mask assembly according to an embodiment.

FIG. 25 to FIG. 34 schematically illustrate a manufacturing process of a mask assembly according to an embodiment.

### DETAILED DESCRIPTION OF THE EMBODIMENTS

In the following description, for the purposes of explanation, numerous details are set forth in order to provide a thorough understanding of various embodiments or implementations. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes.

When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the DR1-axis, the DR2-axis, and the DR3-axis are not limited to three axes of a rectangular coordinate system, such as the X, Y, and Z—axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as understood to mean A only, B only, or any combination of A and B.

Also, “at least one of X, Y, and Z” and “at least one selected from the group consisting of X, Y, and Z” may be construed as X only, Y only, Z only, or any combination of two or more of X, Y, and Z.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

The terminology used herein is for the purpose of describing embodiments and is not intended to be limiting.

As used herein, the singular forms, “a,” “an,” and “the” are intended to include the plural forms as well, unless the context clearly indicates otherwise.

Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in more detail with reference to the accompanying drawings.

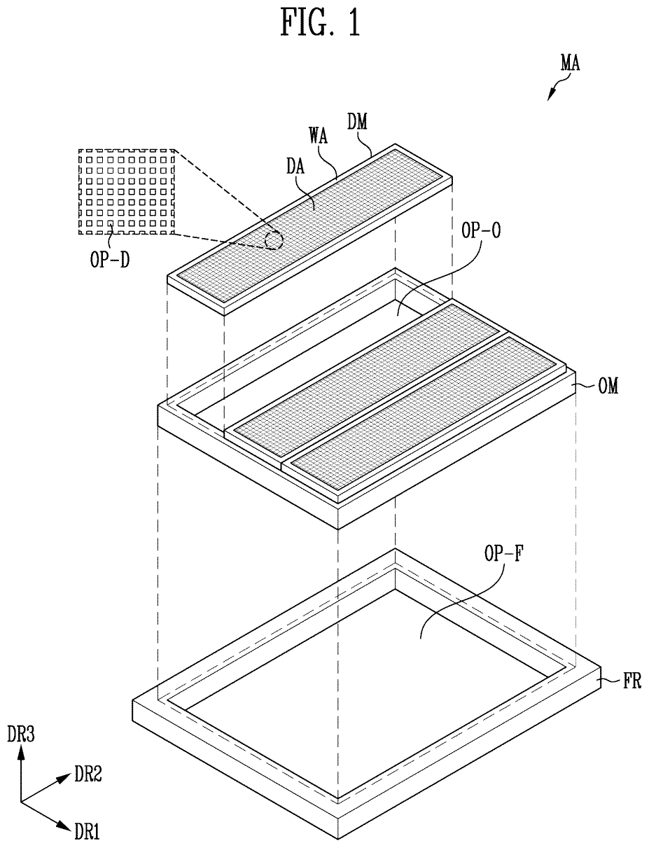

FIG. 1 illustrates a schematic perspective view of a mask assembly according to an embodiment.

Referring to FIG. 1, a mask assembly MA according to an embodiment may include a frame FR, an open mask OM, and a deposition mask DM.

The frame FR may be disposed under or below the open mask OM and the deposition mask DM to support the open mask OM and the deposition mask DM. The frame FR may have a rectangular shape having long sides extending in a first direction DR1 and short sides extending in a second direction DR2 in a plan view. However, the shape of the frame FR is not particularly limited, and any shape capable of supporting the open mask OM and the deposition mask DM is sufficient.

The frame FR may include a frame opening OP-F. For example, the frame opening OP-F may be defined in the frame FR. The deposition material may pass through the frame opening OP-F to pass through the openings defined in the open mask OM and the deposition mask DM. The deposition material may be sprayed in the form of vapor from a deposition source (not shown) disposed below the mask assembly MA. The deposited material may be, for example, a light emitting material that forms a light emitting layer.

The frame FR may be made of a metallic material. For example, the frame FR may include nickel, a nickel-cobalt alloy, a nickel-iron alloy, and the like within the spirit and the scope of the disclosure.

FIG. 1 illustrates, as an example, one frame FR in which one frame opening OP-F is defined, but the disclosure is not limited thereto. For example, a plurality of frame openings OP-F may be defined in the frame FR, and the open mask OM and the deposition mask DM may be supported by a plurality of frames FR.

The open mask OM may be disposed on the frame FR to support the deposition mask DM. The open mask OM may have a rectangular shape having long sides extending in the first direction DR1 and short sides extending in the second direction DR2 in a plan view. However, the shape of the open mask OM is not particularly limited, and any shape that may support the deposition mask DM is sufficient.

The open mask OM may be made of a metallic material. For example, the open mask OM may include at least one of stainless steel, Invar, nickel, cobalt, a nickel alloy, and a nickel-cobalt alloy.

The open mask OM may include a plurality of cell openings OP-O. For example, the plurality of cell openings OP-O may be defined in the open mask OM. The plurality of cell openings OP-O may be arranged (or disposed) in the first direction DR1. FIG. 1 illustrates that the plurality of cell openings OP-O are arranged in 3×1, but the arrangement and number of the plurality of cell openings OP-O are not limited thereto. For example, the plurality of cell openings OP-O may be arranged in the first direction DR1 and the second direction DR2.

Each of the plurality of cell openings OP-O may have a rectangular shape having short sides extending in the first direction DR1 and long sides extending in the second direction DR2 in a plan view. However, the disclosure is not limited thereto, and the shape of each of the plurality of cell openings OP-O may be changed to correspond to the shape of the display device in which the light emitting layer is formed.

In the embodiment, the open mask OM may be used to form a light emitting layer in a medium to large-sized display device. For example, the medium to large-sized display device may include a television, an external billboard, a monitor, a personal computer, a notebook computer, and the like within the spirit and the scope of the disclosure. However, the disclosure is not limited thereto, and the open mask (OM) may also be used to form a light emitting layer of a small to medium-sized display device such as a tablet PC, a smartphone, a car navigation unit, a camera, a center information display (CID) provided in a car, a wrist watch type electronic device, a personal digital assistant (PDA), a portable multimedia player (PMP), and a game console.

The plurality of cell openings OP-O may overlap the frame opening OP-F. Accordingly, the deposition material may be provided to the plurality of cell openings OP-O through the frame opening OP-F.

The plurality of deposition masks DM may be disposed on the open mask OM. The plurality of deposition masks DM may be disposed to correspond to the plurality of cell openings OP-O. For example, each of the plurality of deposition masks DM may be disposed to overlap the corresponding cell opening OP-O.

The plurality of deposition masks DM may be arranged in the first direction DR1. FIG. 1 illustrates that the plurality of deposition masks DM are arranged in 3×1, but the arrangement and number of the plurality of deposition masks DM are not limited thereto. For example, the plurality of deposition masks DM may be arranged in the first direction DR1 and the second direction DR2 corresponding to the plurality of cell openings OP-O.

Each of the plurality of deposition masks DM may have a rectangular shape having short sides extending in the first direction DR1 and long sides extending in the second direction DR2 in a plan view. However, it is not limited thereto, and the shapes of the plurality of deposition masks DM may be respectively changed to correspond to the shapes of the plurality of cell opening OP-O.

The plurality of deposition masks DM may be made of a metallic material. For example, the plurality of deposition masks DM may include at least one of stainless steel, Invar, nickel, cobalt, a nickel alloy, and a nickel-cobalt alloy.

Each of the plurality of deposition masks DM may include a deposition area DA and a welding area WA. For example, the deposition area DA and the welding area WA may be defined in each of the plurality of deposition masks DM.

The deposition area DA may be disposed at a center of the deposition mask DM. The deposition area DA may overlap the cell opening OP-O. The deposition area DA may be an area through which the deposition material passes. The deposition area DA may include a plurality of deposition openings OP-D. For example, the plurality of deposition openings OP-D may be defined in the deposition area DA. The deposition material may pass through the plurality of deposition openings OP-D to be deposited on an object (for example, a base substrate).

The welding area WA may be an area disposed outside the deposition mask DM. The welding area WA may surround the deposition area DA. The welding area WA may be a portion coupled or connected to the open mask OM. For example, the deposition mask DM may be attached to the open mask OM through the welding area WA.

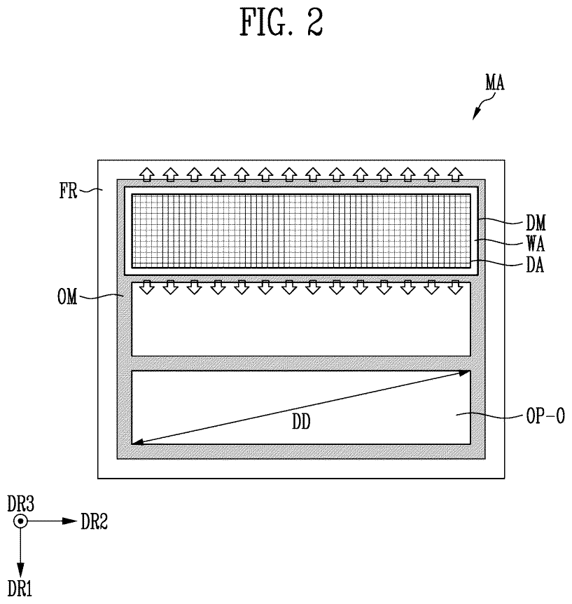

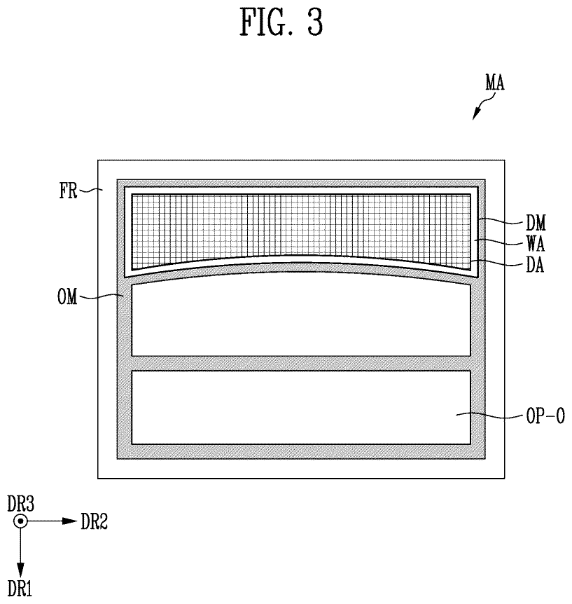

FIG. 2 and FIG. 3 illustrate a manufacturing process of a mask assembly.

The mask assembly MA may be manufactured by attaching the open mask OM to the frame FR and then attaching the deposition mask DM to the open mask OM. Referring to FIG. 2, the deposition mask DM may be stretched so that the deposition area DA of the deposition mask DM corresponds to the cell opening OP-O of the open mask OM. For example, a selectable tensile force may be applied to the deposition mask DM using a stretching machine. Thereafter, the welding area WA of the deposition mask DM may be welded to the open mask OM in a state in which the deposition mask DM is stretched.

Referring to FIG. 3, the process of attaching the deposition mask DM to the open mask OM may be completed by releasing the tensile force applied to the deposition mask DM. In this case, the larger the size of the cell opening OP-O, for example, a diagonal length DD (see FIG. 2), the greater the tensile force applied to the deposition mask DM. As a result, in the process of releasing the tensile force, the shapes of the open mask OM and the deposition mask DM may be deformed, so that the deposition accuracy of the light emitting layer may be deteriorated. For example, in case that the diagonal length DD of the cell opening OP-O is about 11 inches or more, the deterioration in deposition accuracy of the light emitting layer may worsen due to deformation of the shapes of the open mask OM and deposition mask DM.

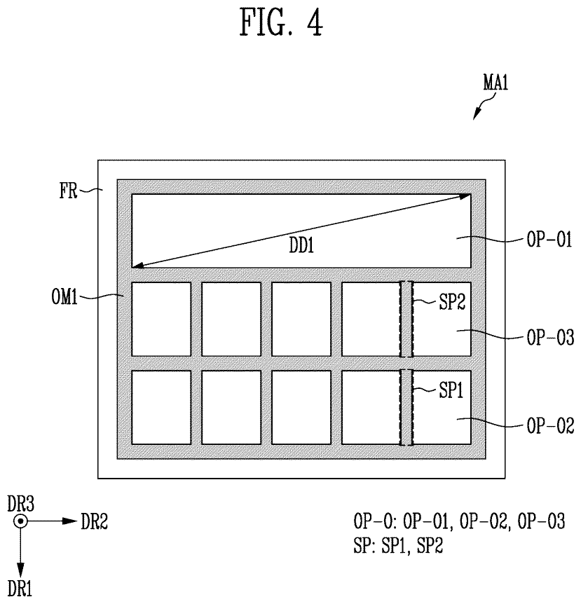

FIG. 4 illustrates a mask assembly according to an embodiment.

Referring to FIG. 4, a mask assembly MAI according to an embodiment may include an open mask OM1 on which a plurality of support portions SP are formed.

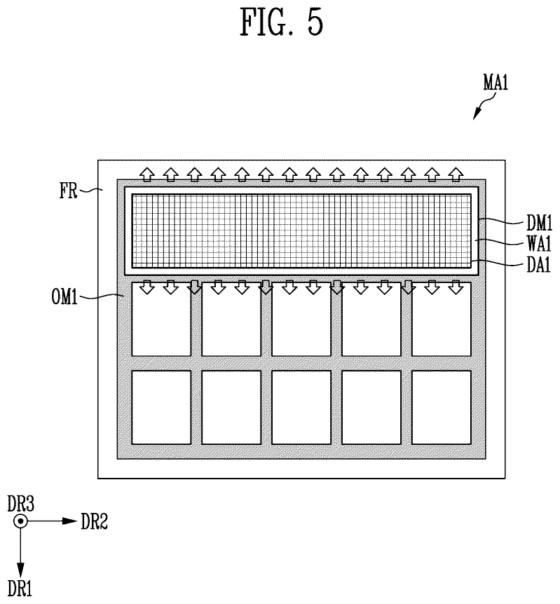

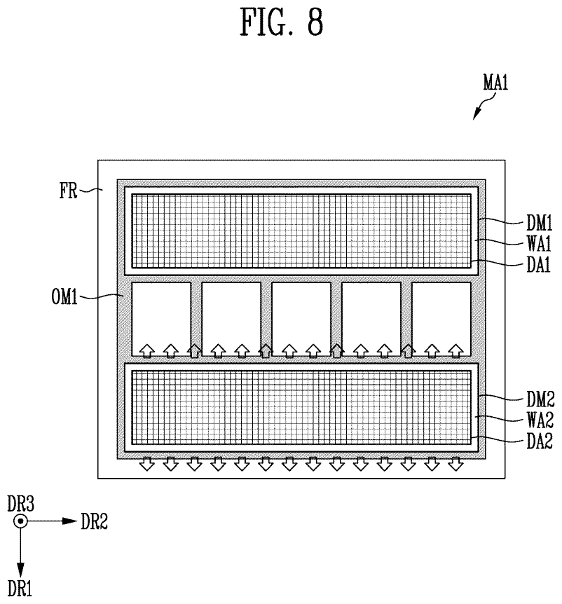

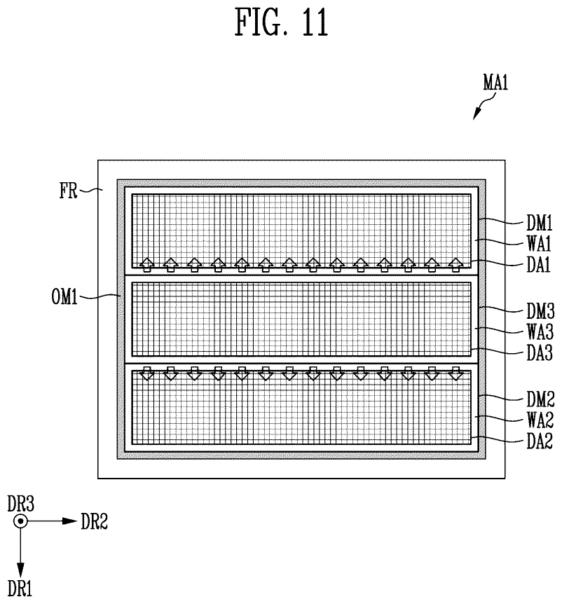

In the embodiment, the open mask OM1 may include a plurality of cell openings OP-O. For example, the plurality of cell openings OP-O may be defined in the open mask OM1. The plurality of cell openings OP-O may be divided according to the order in which a plurality of deposition masks DM1, DM2, and DM3 to be described later are attached to the open mask OM1. For example, a first deposition mask DM1 (see FIG. 5), a second deposition mask DM2 (see FIG. 8), and a third deposition mask DM3 (see FIG. 11) may be sequentially attached to the open mask OM1 to correspond to the first cell opening OP-O1, the second cell opening OP-O2, and the third cell opening OP-O3, respectively. For example, the first deposition mask DM1 may be attached to the open mask OM1 to correspond to the first cell opening OP-O1, and then the second deposition mask DM2 may be attached to correspond to the second cell opening OP-O2, and then the third deposition mask DM3 may be attached to correspond to the third cell opening OP-O3.

The positions and arrangements of the plurality of cell openings OP-O1, OP-O2, and OP-O3 are not limited to the shapes illustrated in FIG. 4. For example, the positions and arrangements of the plurality of cell openings OP-O1, OP-O2, and OP-O3 may be changed according to process conditions.

FIG. 4 illustrates that the open mask OM1 may include three cell openings OP-O, but the number of cell openings OP-O included in the open mask OM1 is not limited thereto. In other words, the number of cell openings OP-O may be changed depending on process conditions.

In the embodiment, the diagonal length DD1 of each of the plurality of cell openings OP-O may be about 11 inches or more. However, the disclosure is not limited thereto, and the diagonal length of each of the plurality of cell openings OP-O may be changed depending on a specifications of a display device to be manufactured.

In the embodiment, the open mask OM1 may include a plurality of support parts SP overlapping the remaining cell openings except for the cell opening at which the process starts among the plurality of cell openings OP-O. For example, the open mask OM1 may include a plurality of support portions SP overlapping the remaining cell openings OP-O2 and OP-O3 except for the first cell opening OP-O1. The plurality of support portions SP may prevent deformation of the open mask OM1 and the first deposition mask DM1 while the first deposition mask DM1 (see FIG. 5) is attached to the open mask OM1 to correspond to the first cell opening OP-O1.

In the embodiment, the plurality of support portions SP may extend in the first direction DR1 and be arranged in the second direction DR2. Although eight support portions SP are illustrated in FIG. 4, the number of the support portions SP is not limited thereto. For example, as the diagonal length DD1 of each of the plurality of cell openings OP-O increases, the number of the support portions SP may increase.

In the embodiment, the plurality of support portions SP may include a plurality of first support portions SP1 and a plurality of second support portions SP2.

The plurality of first support portions SP1 may overlap a cell opening where a subsequent process starts. For example, the plurality of first support portions SP1 may overlap the second cell opening OP-O2. The plurality of first support portions SP1 may be present in the process of attaching the first deposition mask DM1 (see FIG. 5) to the open mask OM1 to correspond to the first cell opening OP-O1, but may be removed thereafter. This will be described later. Although four first support portions SP1 are illustrated in FIG. 4, the number of the first support portions SP1 is not limited thereto.

The plurality of second support portions SP2 may overlap a cell opening where a next subsequent process starts. For example, the plurality of second support portions SP2 may overlap the third cell opening OP-O3. The plurality of second support portions SP2 may be present in the process of attaching the second deposition mask DM2 (see FIG. 8) to the open mask OM1 to correspond to the second cell opening OP-O2, but may be removed thereafter. This will be described later. Although four second support portions SP2 are illustrated in FIG. 4, the number of the second support portions SP2 is not limited thereto.

FIG. 5 to FIG. 12 schematically illustrate a manufacturing process of a mask assembly according to an embodiment.

Referring to FIG. 5, the first deposition mask DM1 may be attached to the open mask OM1 to correspond to the first cell opening OP-O1 (see FIG. 4). First, the first deposition mask DM1 may be stretched so that the deposition area DA1 overlaps the first cell opening OP-O1. For example, a selectable tensile force may be applied to two opposing surfaces of the first deposition mask DM1. Thereafter, the welding area WA1 may be welded to the open mask OM1 in a state in which the first deposition mask DM1 is stretched.

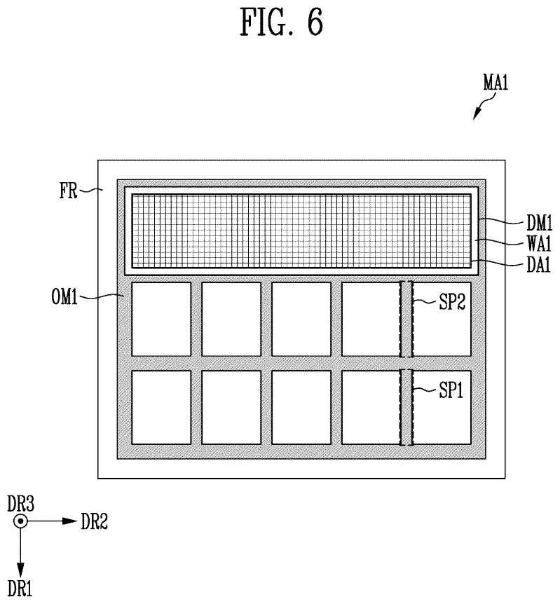

Referring to FIG. 6, the tensile force applied to the first deposition mask DM1 is released, so that the first deposition mask DM1 may be completely attached to the open mask OM1. In this case, deformation of the open mask OM1 and the first deposition mask DM1 may be prevented due to the plurality of first support portion SP1 and the plurality of second support portion SP2. For example, the restoring force generated in case that the tensile force applied to the first deposition mask DM1 is released is distributed to the plurality of first support portions SP1 and the plurality of second support portions SP2, so that deformation of the open mask OM1 and the first deposition mask DM1 may be prevented.

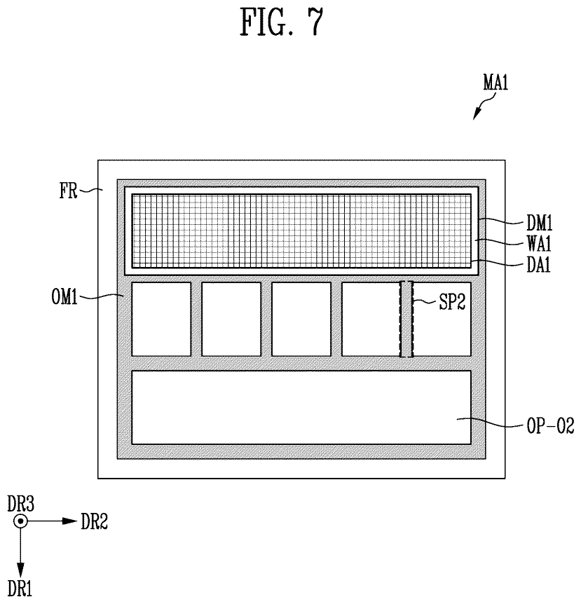

Referring to FIG. 7, after the first deposition mask DM1 is attached to the open mask OM1, the plurality of first support portions SP1 (see FIG. 6) overlapping the second cell opening OP-O2 where a subsequent process starts may be removed. For example, the first support portion SP1 may be removed using a laser. Accordingly, a space of the second cell opening OP-O2 overlapping the deposition area DA2 (see FIG. 8) of the second deposition mask DM2 (see FIG. 8) may be increased. As a result, the deposition material may pass through the second cell opening OP-O2 without interference, thereby improving the deposition reliability of the light emitting layer.

Referring to FIG. 8, the second deposition mask DM2 may be attached to the open mask OM1 to correspond to the second cell opening OP-O2 (see FIG. 7). First, the second deposition mask DM2 may be stretched so that the deposition area DA2 overlaps the second cell opening OP-O2. For example, a selectable tensile force may be applied to two opposing surfaces of the second deposition mask DM2. Thereafter, the welding area WA2 may be welded to the open mask OM1 in a state in which the second deposition mask DM2 is stretched.

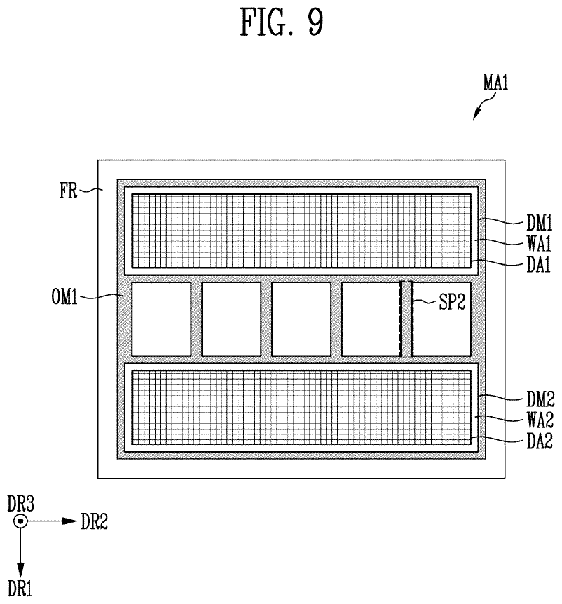

Referring to FIG. 9, the tensile force applied to the second deposition mask DM2 is released, so that the second deposition mask DM2 may be completely attached to the open mask OM1. In this case, deformation of the open mask OM1 and the second deposition mask DM2 may be prevented due to the plurality of second support portion SP2. For example, the restoring force generated in case that the tensile force applied to the second deposition mask DM2 is released is distributed to the plurality of second support portions SP2, so that deformation of the open mask OM1 and the second deposition mask DM2 may be prevented.

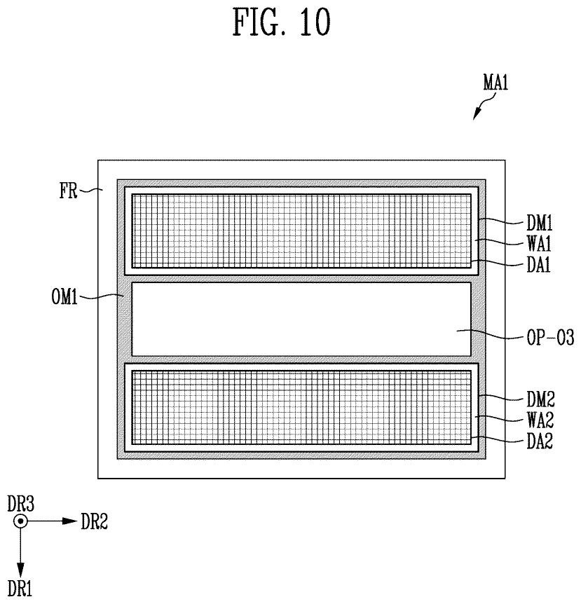

Referring to FIG. 10, after the second deposition mask DM2 is attached to the open mask OM1, the plurality of second support portions SP2 (see FIG. 9) overlapping the third cell opening OP-O3 where a next subsequent process starts may be removed. For example, the second support portion SP2 may be removed using a laser. Accordingly, a space of the third cell opening OP-O3 overlapping the deposition area DA3 (see FIG. 11) of the third deposition mask DM3 (see FIG. 11) may be increased. As a result, the deposition material may pass through the third cell opening OP-O3 without interference, thereby improving the deposition reliability of the light emitting layer.

Referring to FIG. 11, the third deposition mask DM3 may be attached to the open mask OM1 to correspond to the third cell opening OP-O3 (see FIG. 10). First, the third deposition mask DM3 may be stretched so that the deposition area DA3 overlaps the third cell opening OP-O3. For example, a selectable tensile force may be applied to two opposing surfaces of the third deposition mask DM3. Thereafter, the welding area WA3 may be welded to the open mask OM1 in a state in which the third deposition mask DM3 is stretched.

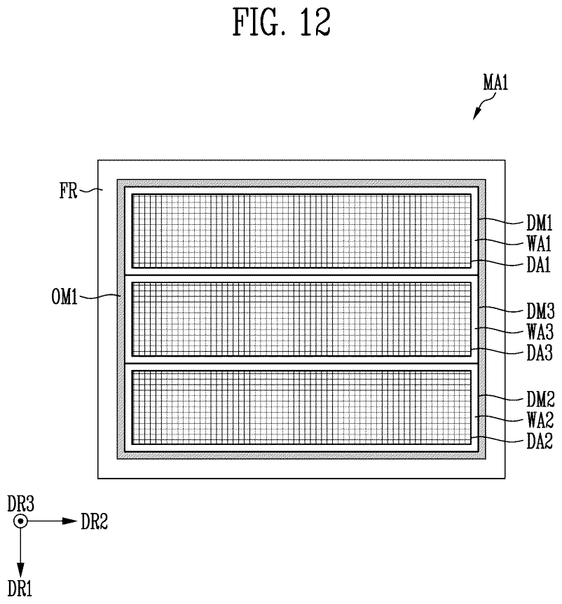

Referring to FIG. 12, the tensile force applied to the third deposition mask DM3 is released, so that the third deposition mask DM3 may be completely attached to the open mask OM1. In this case, since the first deposition mask DM1 and the second deposition mask DM2 adjacent to each other are attached to the open mask OM1, deformation of the open mask OM1 and the third deposition mask DM3 may be prevented. In this way, the mask assembly MAI may be manufactured without deformation of the first deposition mask DM1, the second deposition mask DM2, the third deposition mask DM3, and the open mask OM1, thereby improving deposition accuracy and reliability.

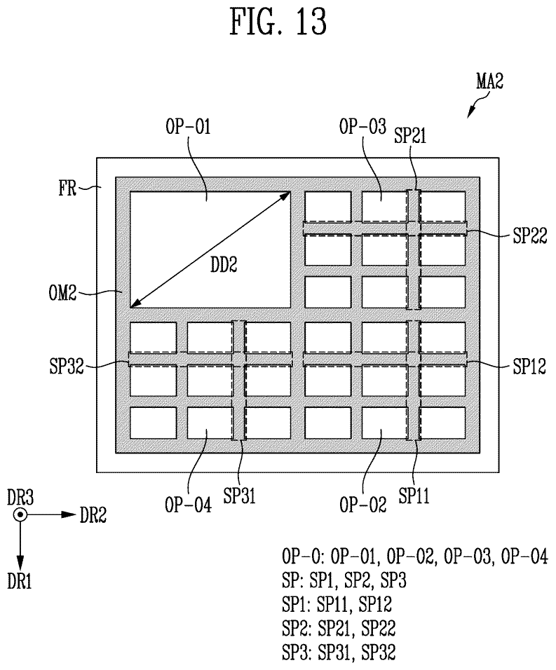

FIG. 13 illustrates a mask assembly according to an embodiment.

Referring to FIG. 13, a mask assembly MA2 according to an embodiment may include an open mask OM2 on which a plurality of support portions SP are formed.

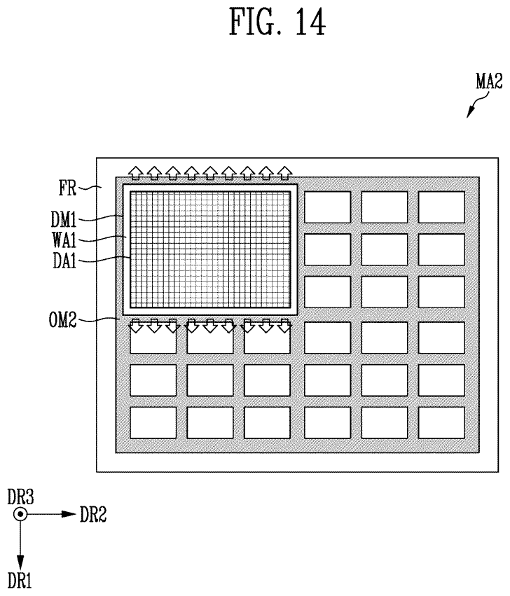

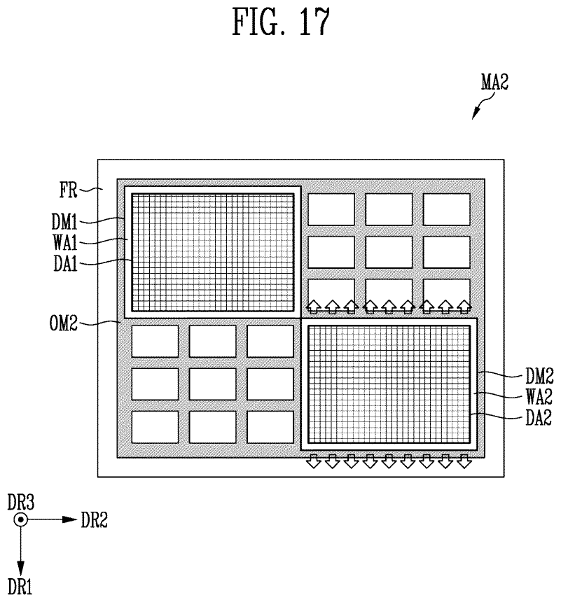

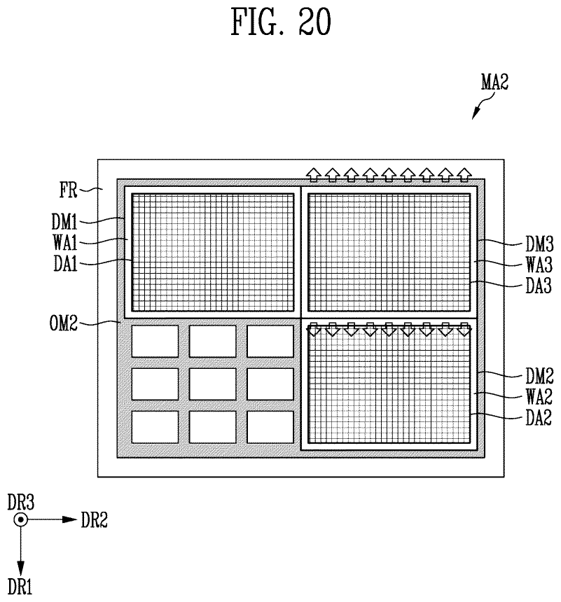

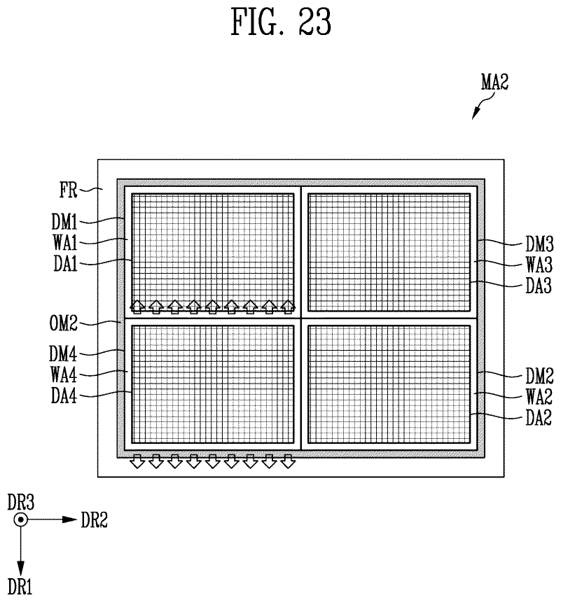

In the embodiment, the open mask OM2 may include a plurality of cell openings OP-O. For example, the plurality of cell openings OP-O may be defined in the open mask OM2. The plurality of cell openings OP-O may be divided according to the order in which a plurality of deposition masks DM1, DM2, DM3, and DM4 to be described later are attached to the open mask OM2. For example, a first deposition mask DM1 (see FIG. 14), a second deposition mask DM2 (see FIG. 17), a third deposition mask DM3 (see FIG. 20), and a fourth deposition mask DM4 (see FIG. 23) may be sequentially attached to the open mask OM2 to correspond to the first cell opening OP-O1, the second cell opening OP-O2, the third cell opening OP-O3, and the fourth cell opening OP-O4, respectively. For example, the first deposition mask DM1 may be attached to the open mask OM2 to correspond to the first cell opening OP-O1, and then the second deposition mask DM2 may be attached to correspond to the second cell opening OP-O2, and then the third deposition mask DM3 may be attached to correspond to the third cell opening OP-O3, and then the fourth deposition mask DM4 may be attached to correspond to the fourth cell opening OP-O4.

The positions and arrangements of the plurality of cell openings OP-O1, OP-O2, OP-O3, and OP-O3 are not limited to the shapes illustrated in FIG. 13. For example, the positions and arrangements of the plurality of cell openings OP-O1, OP-O2, OP-O3, and OP-O4 may be changed according to process conditions.

FIG. 13 illustrates that the open mask OM2 may include four cell openings OP-O, but the number of cell openings OP-O included in the open mask OM2 is not limited thereto. In other words, the number of cell openings OP-O may be changed depending on process conditions.

In the embodiment, the diagonal length DD2 of each of the plurality of cell openings OP-O may be about 11 inches or more. However, the disclosure is not limited thereto, and the diagonal length of each of the plurality of cell openings OP-O may be changed depending on a specifications of a display device to be manufactured.

In the embodiment, the open mask OM2 may include a plurality of support parts SP overlapping the remaining cell openings except for the cell opening at which the process starts among the plurality of cell openings OP-O. For example, the open mask OM2 may include a plurality of support portions SP overlapping the remaining cell openings OP-O2, OP-O3, and OP-O4 except for the first cell opening OP-O1. The plurality of support portions SP may prevent deformation of the open mask OM2 and the first deposition mask DM1 while the first deposition mask DM1 (see FIG. 14) is attached to the open mask OM2 to correspond to the first cell opening OP-O1.

In the embodiment, the plurality of support portions SP may include a plurality of first support portions SP1, a plurality of second support portions SP2, and a plurality of third support portions SP3.

The plurality of first support portions SP1 may overlap a cell opening where a subsequent process starts. For example, the plurality of first support portions SP1 may overlap the second cell opening OP-O2. The plurality of first support portions SP1 may be present in the process of attaching the first deposition mask DM1 (see FIG. 14) to the open mask OM2 to correspond to the first cell opening OP-O1, but may be removed thereafter. This will be described later. Although four first support portions SP1 are illustrated in FIG. 13, the number of the first support portions SP1 is not limited thereto. In other words, the number of the first support portions SP1 may be changed depending on process conditions.

In the embodiment, the plurality of first support portions SP1 may include a plurality of sub-support portions SP11 extending in the first direction DR1 and arranged in the second direction DR2, and a plurality of sub-support portions SP12 extending in the second direction DR2 and arranged in the first direction DR1. FIG. 13 illustrates two sub-support portions SP11 and two sub-support portions SP12, but the number of the sub-support portions SP11 and SP12 is not limited thereto. In other words, the number of the sub-support portions SP11 and SP12 may be changed depending on process conditions.

The plurality of second support portions SP2 may overlap a cell opening where a next subsequent process starts. For example, the plurality of second support portions SP2 may overlap the third cell opening OP-O3. The plurality of second support portions SP2 may be present in the process of attaching the second deposition mask DM2 (see FIG. 17) to the open mask OM2 to correspond to the second cell opening OP-O2, but may be removed thereafter. This will be described later. Although four second support portions SP2 are illustrated in FIG. 13, the number of the second support portions SP2 is not limited thereto. In other words, the number of the second support portions SP2 may be changed depending on process conditions.

In the embodiment, the plurality of second support portions SP2 may include a plurality of sub-support portions SP21 extending in the first direction DR1 and arranged in the second direction DR2, and a plurality of sub-support portions SP22 extending in the second direction DR2 and arranged in the first direction DR1. FIG. 13 illustrates two sub-support portions SP21 and two sub-support portions SP22, but the number of the sub-support portions SP21 and SP22 is not limited thereto. In other words, the number of the sub-support portions SP21 and SP22 may be changed depending on process conditions.

The plurality of third support portions SP3 may overlap a cell opening where a next subsequent process starts. For example, the plurality of third support portions SP3 may overlap the fourth cell opening OP-O4. The plurality of third support portions SP3 may be present in the process of attaching the third deposition mask DM3 (see FIG. 20) to the open mask OM2 to correspond to the third cell opening OP-O3, but may be removed thereafter. This will be described later. Although four third support portions SP3 are illustrated in FIG. 13, the number of the third support portions SP3 is not limited thereto. In other words, the number of the third support portions SP3 may be changed depending on process conditions.

In the embodiment, the plurality of third support portions SP3 may include a plurality of sub-support portions SP31 extending in the first direction DR1 and arranged in the second direction DR2, and a plurality of sub-support portions SP32 extending in the second direction DR2 and arranged in the first direction DR1. FIG. 13 illustrates two sub-support portions SP31 and two sub-support portions SP32, but the number of the sub-support portions SP31 and SP32 is not limited thereto. In other words, the number of the sub-support portions SP31 and SP32 may be changed depending on process conditions.

FIG. 14 to FIG. 24 schematically illustrate a manufacturing process of a mask assembly according to an embodiment.

Referring to FIG. 14, the first deposition mask DM1 may be attached to the open mask OM2 to correspond to the first cell opening OP-O1 (see FIG. 13). First, the first deposition mask DM1 may be stretched so that the deposition area DA1 overlaps the first cell opening OP-O1. For example, a selectable tensile force may be applied to two opposing surfaces of the first deposition mask DM1. Thereafter, the welding area WA1 may be welded to the open mask OM2 in a state in which the first deposition mask DM1 is stretched.

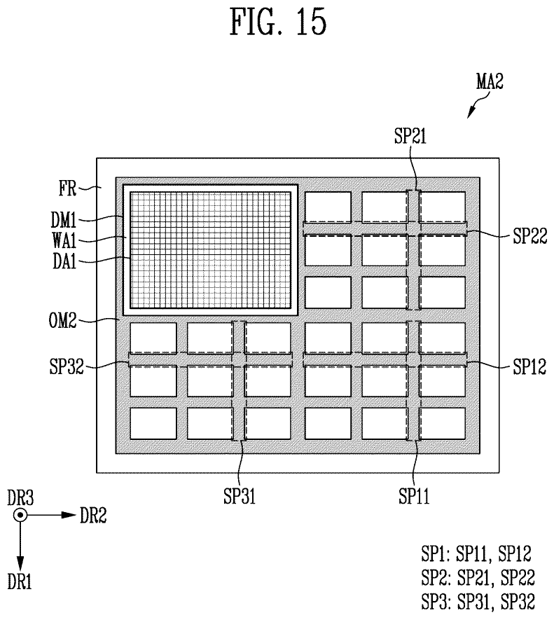

Referring to FIG. 15, the tensile force applied to the first deposition mask DM1 is released, so that the first deposition mask DM1 may be completely attached to the open mask OM2. In this case, deformation of the open mask OM2 and the first deposition mask DM1 may be prevented due to the plurality of first support portion SP1, the plurality of second support portion SP2, and the plurality of third support portion SP3. For example, the restoring force generated in case that the tensile force applied to the first deposition mask DM1 is released is distributed to the plurality of first support portions SP1, the plurality of second support portions SP2, and the plurality of third support portion SP3, so that deformation of the open mask OM2 and the first deposition mask DM1 may be prevented.

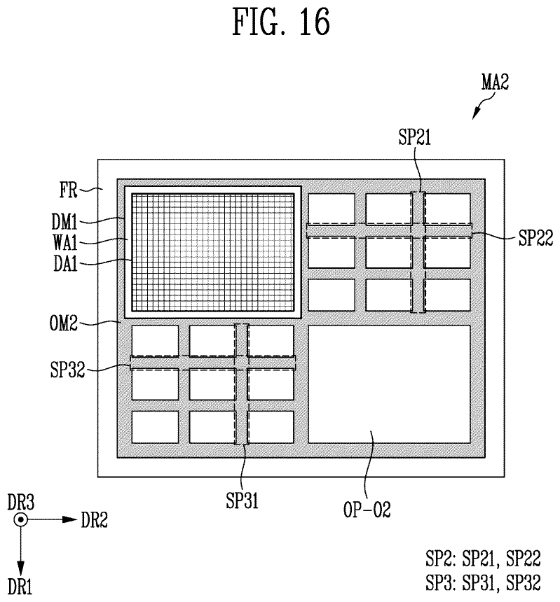

Referring to FIG. 16, after the first deposition mask DM1 is attached to the open mask OM2, the plurality of first support portions SP1 (see FIG. 15) overlapping the second cell opening OP-O2 where a subsequent process starts may be removed. For example, the first support portion SP1 may be removed using a laser. Accordingly, a space of the second cell opening OP-O2 overlapping the deposition area DA2 (see FIG. 17) of the second deposition mask DM2 (see FIG. 17) may be increased. As a result, the deposition material may pass through the second cell opening OP-O2 without interference, thereby improving the deposition reliability of the light emitting layer.

Referring to FIG. 17, the second deposition mask DM2 may be attached to the open mask OM2 to correspond to the second cell opening OP-O2 (see FIG. 16). First, the second deposition mask DM2 may be stretched so that the deposition area DA2 overlaps the second cell opening OP-O2. For example, a selectable tensile force may be applied to two opposing surfaces of the second deposition mask DM2. Thereafter, the welding area WA2 may be welded to the open mask OM2 in a state in which the second deposition mask DM2 is stretched.

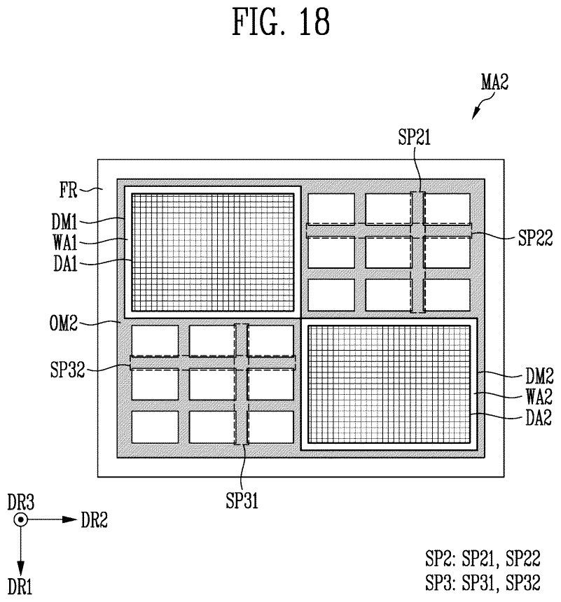

Referring to FIG. 18, the tensile force applied to the second deposition mask DM2 is released, so that the second deposition mask DM2 may be completely attached to the open mask OM2. In this case, deformation of the open mask OM2 and the second deposition mask DM2 may be prevented due to the plurality of second support portion SP2. For example, the restoring force generated in case that the tensile force applied to the second deposition mask DM2 is released is distributed to the plurality of second support portions SP2 and the third support portions SP3, so that deformation of the open mask OM2 and the second deposition mask DM2 may be prevented.

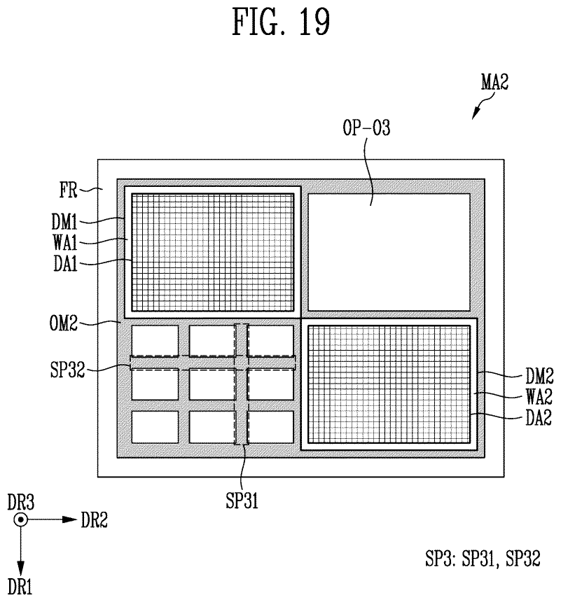

Referring to FIG. 19, after the second deposition mask DM2 is attached to the open mask OM2, the plurality of second support portions SP2 (see FIG. 18) overlapping the third cell opening OP-O3 where a next subsequent process starts may be removed. For example, the second support portion SP2 may be removed using a laser. Accordingly, a space of the third cell opening OP-O3 overlapping the deposition area DA3 (see FIG. 20) of the third deposition mask DM3 (see FIG. 20) may be increased. As a result, the deposition material may pass through the third cell opening OP-O3 without interference, thereby improving the deposition reliability of the light emitting layer.

Referring to FIG. 20, the third deposition mask DM3 may be attached to the open mask OM2 to correspond to the third cell opening OP-O3 (see FIG. 19). First, the third deposition mask DM3 may be stretched so that the deposition area DA3 overlaps the third cell opening OP-O3. For example, a selectable tensile force may be applied to two opposing surfaces of the third deposition mask DM3. Thereafter, the welding area WA3 may be welded to the open mask OM2 in a state in which the third deposition mask DM3 is stretched.

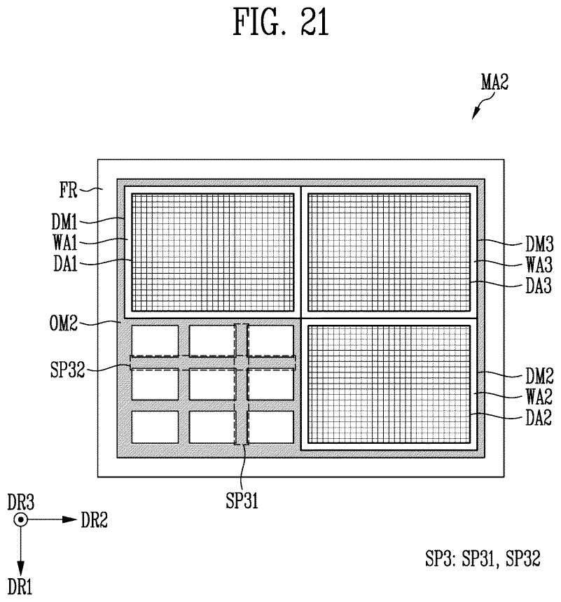

Referring to FIG. 21, the tensile force applied to the third deposition mask DM3 is released, so that the third deposition mask DM3 may be completely attached to the open mask OM2. In this case, deformation of the open mask OM2 and the third deposition mask DM3 may be prevented due to the plurality of third support portion SP3. For example, the restoring force generated in case that the tensile force applied to the third deposition mask DM3 is released is distributed to the plurality of third support portions SP3, so that deformation of the open mask OM2 and the third deposition mask DM3 may be prevented.

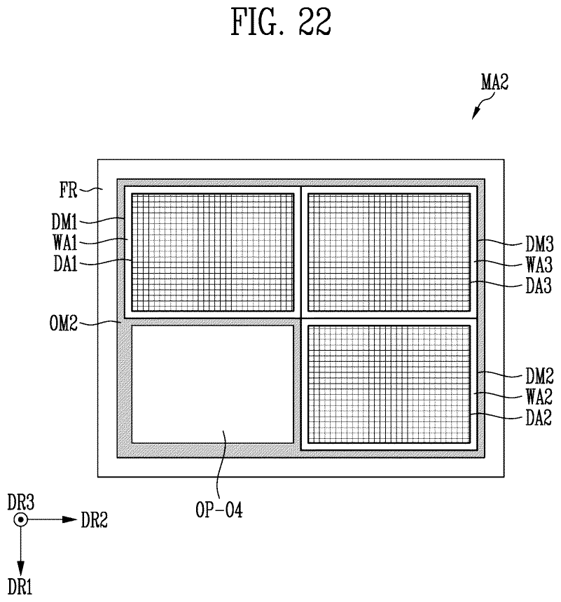

Referring to FIG. 22, after the third deposition mask DM3 is attached to the open mask OM2, the plurality of third support portions SP3 (see FIG. 21) overlapping the fourth cell opening OP-O4 where a next subsequent process starts may be removed. For example, the third support portion SP3 may be removed using a laser. Accordingly, a space of the fourth cell opening OP-O4 overlapping the deposition area DA4 (see FIG. 23) of the fourth deposition mask DM4 (see FIG. 23) may be increased. As a result, the deposition material may pass through the fourth cell opening OP-O4 without interference, thereby improving the deposition reliability of the light emitting layer.

Referring to FIG. 23, the fourth deposition mask DM4 may be attached to the open mask OM2 to correspond to the fourth cell opening OP-O4 (see FIG. 22). First, the fourth deposition mask DM4 may be stretched so that the deposition area DA4 overlaps the fourth cell opening OP-O4. For example, a selectable tensile force may be applied to two opposing surfaces of the fourth deposition mask DM4. Thereafter, the welding area WA4 may be welded to the open mask OM2 in a state in which the fourth deposition mask DM4 is stretched.

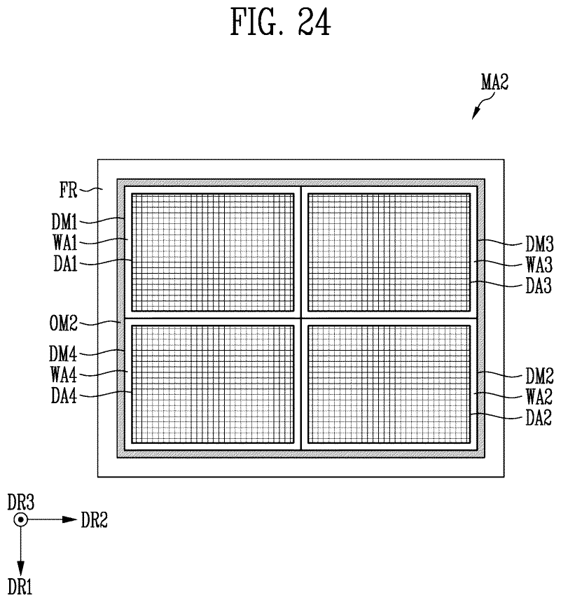

Referring to FIG. 24, the tensile force applied to the fourth deposition mask DM4 is released, so that the fourth deposition mask DM4 may be completely attached to the open mask OM2. In this case, since the first deposition mask DM1, the second deposition mask DM2, and the third deposition mask DM3, which are adjacent to each other, are attached to the open mask OM2, deformation of the open mask OM2 and the fourth deposition mask DM4 may be prevented. In this way, the mask assembly MA2 may be manufactured without deformation of the first deposition mask DM1, the second deposition mask DM2, the third deposition mask DM3, the fourth deposition mask DM4, and the open mask OM2, thereby improving deposition accuracy and reliability.

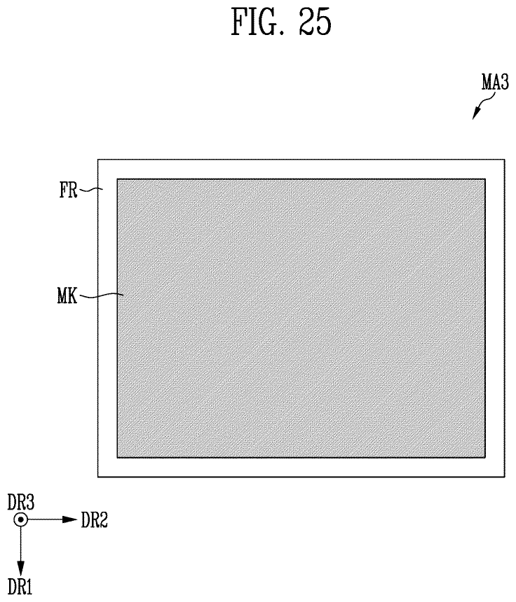

FIG. 25 to FIG. 34 schematically illustrate a manufacturing process of a mask assembly according to an embodiment.

Referring to FIG. 25, a mask MK may be attached to a frame FR. In the embodiment, the mask MK may be attached to the frame FR without an opening being formed. For example, the mask MK may be different from the open mask OM (see FIG. 2) attached to the frame FR in a state in which a plurality of openings OP-O (see FIG. 2) are formed.

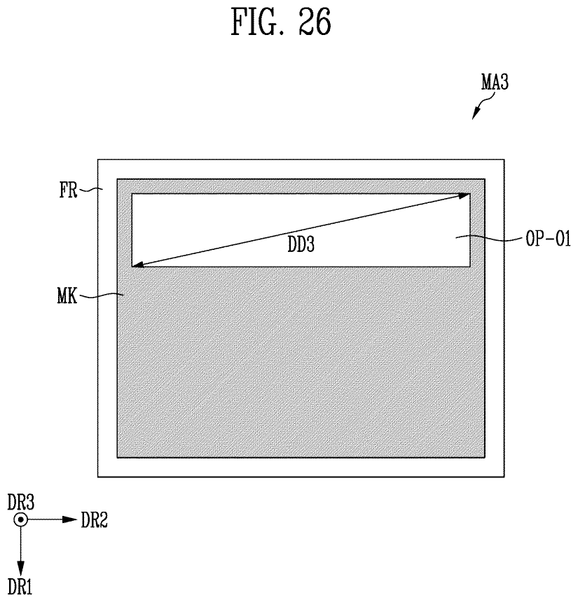

Referring to FIG. 26, a cell opening at which a process starts may be formed in the mask MK. For example, the first cell opening OP-O1 may be formed in the mask MK. The first cell opening OP-O1 may be formed by irradiating the mask MK with a laser beam. The position of the first cell opening OP-O1 is not limited to the shape shown in FIG. 26, and may be changed depending on process conditions. In the embodiment, the diagonal length DD3 of the first cell opening OP-O1 may be about 11 inches or more. However, the disclosure is not limited thereto, and the diagonal length DD3 of the first cell opening OP-O1 may be changed depending on a specifications of a display device to be manufactured.

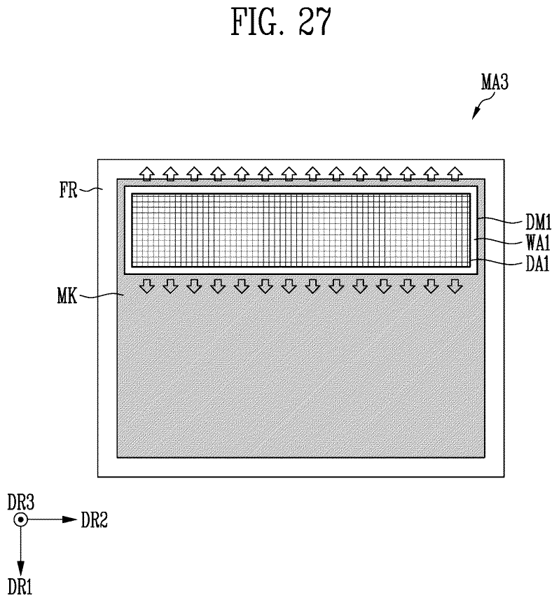

Referring to FIG. 27, the first deposition mask DM1 may be attached to the mask MK to correspond to the first cell opening OP-O1 (see FIG. 26). First, the first deposition mask DM1 may be stretched so that the deposition area DA1 overlaps the first cell opening OP-O1. For example, a selectable tensile force may be applied to two opposing surfaces of the first deposition mask DM1. Thereafter, the welding area WA1 may be welded to the mask MK in a state in which the first deposition mask DM1 is stretched.

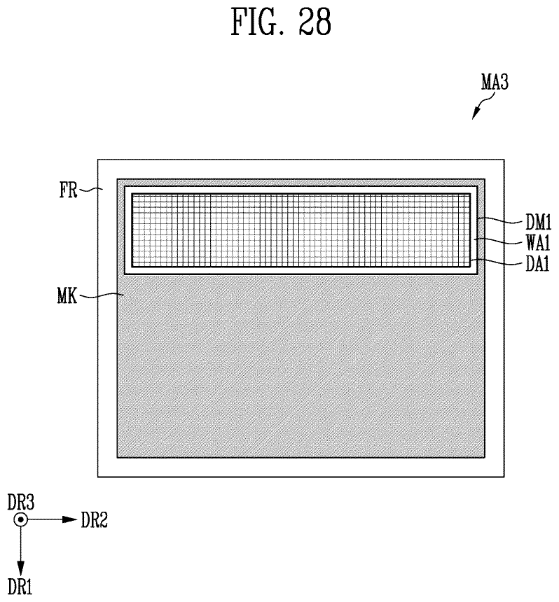

Referring to FIG. 28, the tensile force applied to the first deposition mask DM1 is released, so that the first deposition mask DM1 may be completely attached to the mask MK. In this case, a separate cell opening is not formed in the mask MK except for the first cell opening OP-O1 (see FIG. 26), and thus deformation of the mask MK and the first deposition mask DM1 may be prevented. For example, the restoring force generated in case that the tensile force applied to the first deposition mask DM1 is released is distributed throughout the mask MK, so deformation of the mask MK and the first deposition mask DM1 may be prevented.

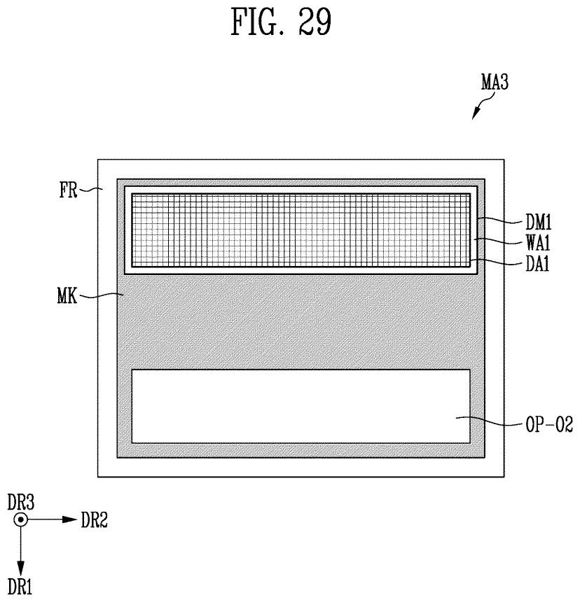

Referring to FIG. 29, a cell opening at which a subsequent process starts may be formed in the mask MK. For example, the second cell opening OP-O2 may be formed in the mask MK. The second cell opening OP-O2 may be formed by irradiating the mask MK with a laser beam. The position of the second cell opening OP-O2 is not limited to the shape shown in FIG. 29, and may be changed depending on process conditions. The diagonal length of the second cell opening OP-O2 may be the same as the diagonal length DD3 (see FIG. 26) of the first cell opening OP-O1 (see FIG. 26). However, the disclosure is not limited thereto, and the diagonal length of the second cell opening OP-O2 may be changed depending on a specification of a display device to be manufactured to be different from the diagonal length DD3 of the first cell opening OP-O1.

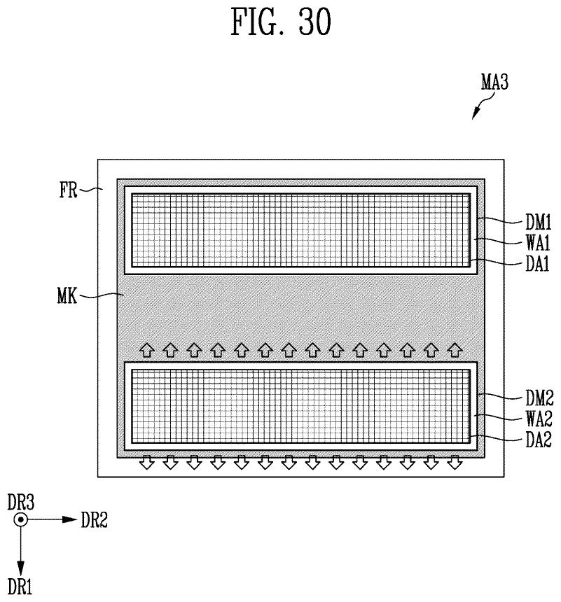

Referring to FIG. 30, the second deposition mask DM2 may be attached to the mask MK to correspond to the second cell opening OP-O2 (see FIG. 29). First, the second deposition mask DM2 may be stretched so that the deposition area DA2 overlaps the second cell opening OP-O2. For example, a selectable tensile force may be applied to two opposing surfaces of the second deposition mask DM2. Thereafter, the welding area WA2 may be welded to the mask MK in a state in which the second deposition mask DM2 is stretched.

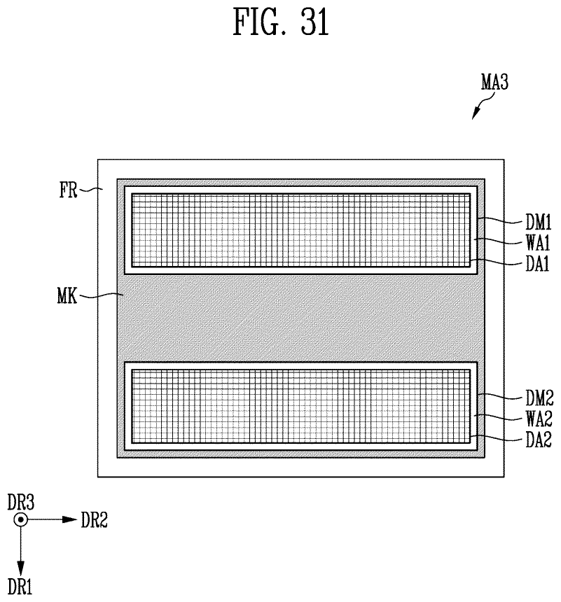

Referring to FIG. 31, the tensile force applied to the second deposition mask DM2 is released, so that the second deposition mask DM2 may be completely attached to the mask MK. In this case, a separate cell opening is not formed in the mask MK except for the first cell opening OP-O1 (see FIG. 26) and the second cell opening OP-O2 (see FIG. 29), and thus deformation of the mask MK and the second deposition mask DM2 may be prevented. For example, the restoring force generated in case that the tensile force applied to the second deposition mask DM2 is released is distributed throughout the mask MK, so deformation of the mask MK and the second deposition mask DM2 may be prevented.

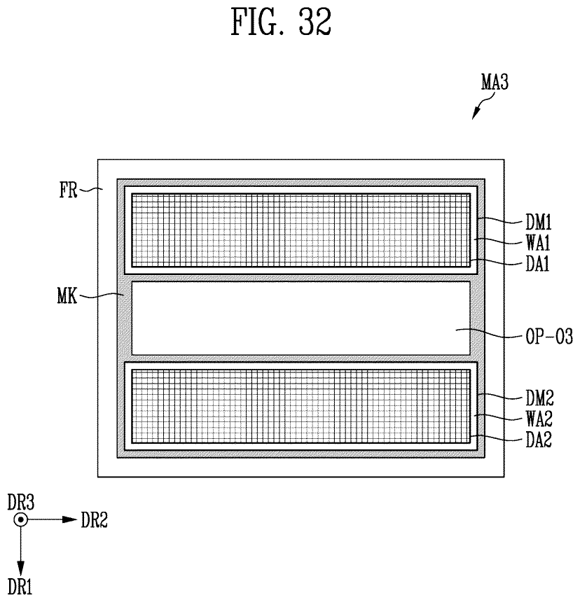

Referring to FIG. 32, a cell opening at which a next subsequent process starts may be formed in the mask MK. For example, the third cell opening OP-O3 may be formed in the mask MK. The third cell opening OP-O3 may be formed by irradiating the mask MK with a laser beam. The position of the third cell opening OP-O3 is not limited to the shape shown in FIG. 32, and may be changed depending on process conditions. The diagonal length of the third cell opening OP-O3 may be the same as the diagonal length DD3 (see FIG. 26) of the first cell opening OP-O1 (see FIG. 26). However, the disclosure is not limited thereto, and the diagonal length of the third cell opening OP-O3 may be changed depending on a specification of a display device to be manufactured to be different from the diagonal length DD3 of the first cell opening OP-O1.

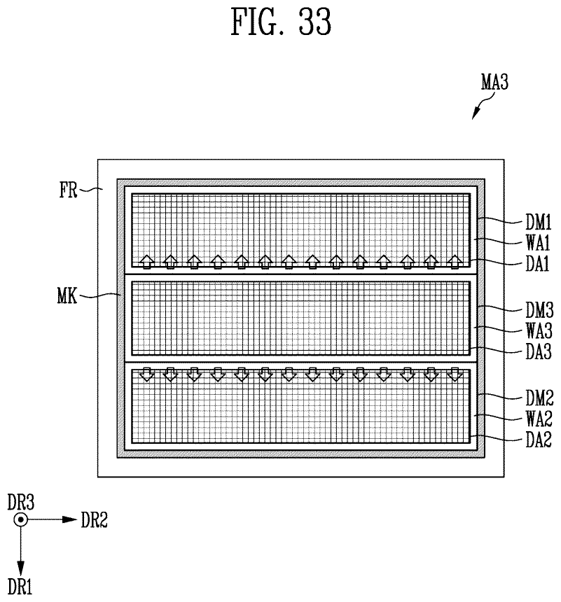

Referring to FIG. 33, the third deposition mask DM3 may be attached to the mask MK to correspond to the third cell opening OP-O3 (see FIG. 32). First, the third deposition mask DM3 may be stretched so that the deposition area DA3 overlaps the third cell opening OP-O3. For example, a selectable tensile force may be applied to two opposing surfaces of the third deposition mask DM3. Thereafter, the welding area WA3 may be welded to the mask MK in a state in which the third deposition mask DM3 is stretched.

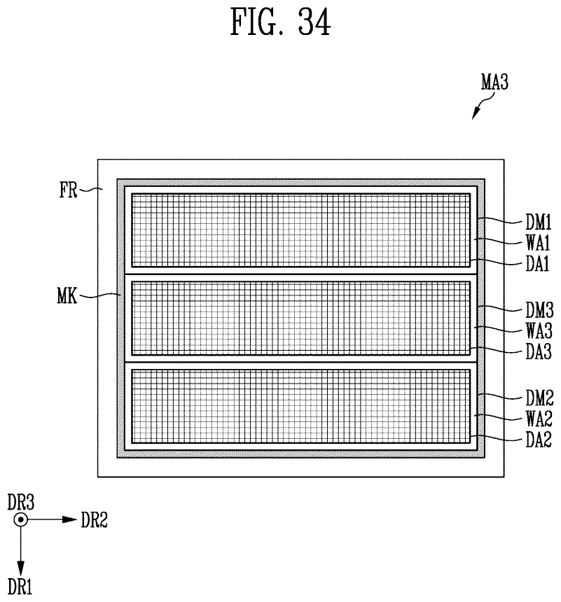

Referring to FIG. 34, the tensile force applied to the third deposition mask DM3 is released, so that the third deposition mask DM3 may be completely attached to the mask MK. In this case, since the first deposition mask DM1 and the second deposition mask DM2 adjacent to each other are attached to the mask MK, deformation of the mask OM1 and the third deposition mask DM3 may be prevented. In this way, the mask assembly MA3 may be manufactured without deformation of the first deposition mask DM1, the second deposition mask DM2, the third deposition mask DM3, and the mask MK, thereby improving deposition accuracy and reliability.

Although the disclosure has been described according to the above-described embodiments, it should be noted that the above-described embodiments are for describing the disclosure and not for limiting the scope of the disclosure. Those of ordinary skill in the art to which the disclosure pertains will understand that various modifications are possible within the scope of the technical spirit of the disclosure.

The scope of the disclosure is not limited to the details described in the detailed description of the specification, but should also be defined by the claims. It is to be construed that all changes or modifications derived from the meaning and scope of the claims and equivalent concepts thereof are included in the scope of the disclosure.

What is claimed is:

1. A mask assembly comprising:
a frame including a frame opening; and
an open mask including a plurality of cell openings overlapping the frame opening,
wherein the open mask further includes a plurality of support portions overlapping remaining cell openings except a first cell opening among the plurality of cell openings.

2. The mask assembly of claim 1, wherein each of the plurality of cell openings has a substantially rectangular shape.

3. The mask assembly of claim 2, wherein a diagonal length of each of the plurality of cell openings is about 11 inches or more.

4. The mask assembly of claim 1, further comprising:
a first deposition mask including a first deposition area overlapping the first cell opening.

5. The mask assembly of claim 1, wherein each of the plurality of support portions extends in a first direction and is disposed in a second direction perpendicular to the first direction.

6. The mask assembly of claim 1, wherein the plurality of support portions include:
a plurality of first sub-support portions each extending in a first direction and disposed in a second direction substantially perpendicular to the first direction; and
a plurality of second sub-support portions each extending in the second direction and disposed in the first direction.

7. A method of manufacturing a mask assembly, the method comprising:
manufacturing an open mask including n cell openings, where n is a natural number of 3 or more, and a plurality of support portions overlapping remaining cell openings except a first cell opening among the n cell openings;
attaching the open mask to a frame including a frame opening so that the plurality of cell openings overlap the frame opening; and
attaching a first deposition mask including a first deposition area to the open mask so that the first deposition area overlaps the first cell opening.

8. The method of claim 7, further comprising:
removing support part portions that overlap a k-th cell opening following a (k-l)-th cell opening among the plurality of support portions; and
attaching a k-th deposition mask in which a k-th deposition area is defined to the open mask so that the k-th deposition area overlaps the k-th cell opening, where k is a natural number of 2 or more and n or less.

9. The method of claim 8, wherein the removing of the support part portions and the attaching of the k-th deposition mask are repeated until the value of k becomes n.

10. The method of claim 7, wherein the attaching includes:
applying a tensile force to the first deposition mask;
welding the stretched first deposition mask to the open mask; and
releasing the tensile force.

11. The method of claim 8, wherein the attaching includes:
applying a tensile force to the k-th deposition mask;
welding the stretched k-th deposition mask to the open mask; and
releasing the tensile force.

12. The method of claim 7, wherein each of the n cell openings has a substantially rectangular shape.

13. The method of claim 12, wherein a diagonal length of each of the n cell openings is about 11 inches or more.

14. The method of claim 7, wherein each of the plurality of support portions extends in a first direction and is disposed in a second direction substantially perpendicular to the first direction.

15. The method of claim 7, wherein the plurality of support portions include:
a plurality of first sub-support portions each extending in a first direction and disposed in a second direction substantially perpendicular to the first direction; and
a plurality of second sub-support portions each extending in the second direction and disposed in the first direction.

16. A method of manufacturing of a mask assembly, the method comprising:
attaching a mask to a frame including a frame opening;
forming a k-th cell opening in the mask; and
attaching a k-th deposition mask including a k-th deposition area to the mask so that the k-th deposition area overlaps the k-th cell opening, where k is a natural number greater than or equal to 1 and less than or equal to n, and n is a natural number greater than or equal to 3.

17. The method of claim 16, wherein the forming of the k-th cell opening and the attaching of the k-th deposition mask are repeated until the value of k becomes n.

18. The method of claim 17, wherein the k-th cell opening is formed by irradiating the mask with a laser beam.

19. The method of claim 16, wherein the k-th cell opening has a substantially rectangular shape.

20. The method of claim 19, wherein a diagonal length of the k-th cell opening is about 11 inches or more.
